(19) United States
(12) Patent Application Publication
(10) Pub. No.: US 2019/0305186 A1
(43) Pub. Date: Oct. 3, 2019

(54) LIGHT-EMITTING ELEMENT

(71) Applicant: LG INNOTEK CO., LTD., Seoul (KR)

(72) Inventor: Duk Hyun PARK, Seoul (KR)

(73) Assignee: LG INNOTEK CO., LTD., Seoul (KR)

(21) Appl. No.: 16/065,316

(22) PCT Filed: Dec. 13, 2016
(86) PCT No.: PCT/KR2016/014559

§ 371 Date: Jun. 22, 2018

(30) Foreign Application Priority Data
Dec. 23, 2015 (KR) 10-2015-0184755

(51) Int. Cl. H01L 33/36; H01L 33/60; H01L 33/00

(52) U.S. Cl. CPC H01L 33/36; H01L 33/0008; H01L 33/60

(57) ABSTRACT

An embodiment provides a light-emitting element comprising: a light-emitting structure including a first conductive semiconductor layer, an active layer, and a second conductive semiconductor layer; a first ohmic layer disposed on the first conductive semiconductor layer and having an opening part formed through a first region thereof; a first electrode disposed on a second region of the ohmic layer, and a second electrode disposed on the second conductive semiconductor layer.

### TECHNICAL FIELD

Embodiments relate to a light-emitting element, and more particularly, to a light-emitting element for emitting light in a specific direction.

### BACKGROUND ART

Group 3 to 5 compound semiconductors such as GaN or AlGaN have been widely used for optoelectronics and electronic devices due to many advantages thereof such as wide and easily adjustable band gap energy.

In particular, a light-emitting element such as a light emitting diode or a laser diode using groups 3 to 5 or 2 to 6 compound semiconductor materials of a semiconductor is capable of realizing various colors such as red, green, blue, and ultraviolet by virtue of thin film growth technologies and device materials, is also capable of realizing white light with high efficiency using a fluorescent material or via color combination, and advantageously has low power consumption, semi-permanent lifetime, rapid response speed, safety, and environmental friendliness compared with an existing light source such as a fluorescent lamp and an incandescent lamp.

Accordingly, the light-emitting element has been expansively applied to a transmission module of an optical communication device, a light-emitting diode backlight replacing a cold cathode fluorescent lamp (CCFL) included in a backlight of a liquid crystal display (LCD) display device, a light-emitting diode illumination device replacing a fluorescent lamp or an incandescent lamp, a vehicle headlight, and a traffic light.

FIGS. 1 and 2 are diagrams showing a conventional light-emitting element and light-emitting element package.

A conventional light-emitting element 100 may be configured in such a way that a light-emitting structure 120 including a first conductive-type semiconductor layer 122, an active layer 124, and a second conductive-type semiconductor layer 126 is disposed on a substrate 110 and a first electrode 162 and a second electrode 166 are disposed on the first conductive-type semiconductor layer 122 and the second conductive-type semiconductor layer 126, respectively.

The light-emitting element 100 emits light with energy determined by a unique energy band of a material included in the active layer 124 via recombination between electronics injected through the first conductive-type semiconductor layer 122 and holes injected through the second conductive-type semiconductor layer 126. In this case, light emitted from the active layer 124 may also be emitted from an upper portion, a lower portion, or a lateral surface of the light-emitting element 100.

A light-emitting package 200 of FIG. 2 may include a body 210 with a cavity formed therein, a first lead frame 221 and a second lead frame 222 installed on the body 210, the light-emitting element 100 disposed on a bottom surface of the cavity of the body 210 and electrically connected to the first lead frame 221 and the second lead frame 222 through wires 232 and 236, and a molding portion 250 formed in the cavity.

The light-emitting package 200 of FIG. 2 is configured in such a way that the cavity is formed in the body 210 to reflect and transmit light emitted from the light-emitting element 100 from the bottom surface or lateral wall of the cavity and, thus, may adjust a directed angle of light emitted from the light-emitting element 100.

However, there is a limit in adjusting a path of light emitted from a light-emitting element only by the aforementioned structure of the cavity and, in particular, there is a need to reduce a volume of a light source of a light-emitting element used as a light source of a mobile device.

### DISCLOSURE

### Technical Problem

Embodiments provide a light-emitting element for transmitting light emitted therefrom in a specific direction and reducing the volume of a light source.

### Technical Solution

In one embodiment, a light-emitting element includes a light-emitting structure including a first conductive-type semiconductor layer, an active layer, and a second conductive-type semiconductor layer, a first ohmic layer disposed on the first conductive-type semiconductor layer and including an open region formed in a first region, a first electrode disposed in a second region on the first ohmic layer, and a second electrode disposed on the second conductive-type semiconductor layer.

The light-emitting element may further include a reflective layer disposed between the second conductive-type semiconductor layer and the second electrode.

The light-emitting element may further include a second ohmic layer disposed between the second conductive-type semiconductor layer and the reflective layer.

The light-emitting element may further include a transmissive insulating layer disposed between the second conductive-type semiconductor layer and the reflective layer, wherein the second ohmic layer is patterned and arranged.

The second ohmic layer may be arranged in a third region corresponding to the open region and a fourth region at an edge of the light-emitting structure.

The transmissive insulating layer may be disposed in an entire region between the third region and the fourth region between the second conductive-type semiconductor layer and the reflective layer.

The sum of cross sections of the second ohmic layers in a horizontal direction may be 3% to 4% of a cross section of the active layer in a horizontal direction.

The second ohmic layer may include a plurality of cells and each cell may have a size of 5 to 15 micrometers in a horizontal direction.

The first conductive-type semiconductor layer may be doped with an n-type dopant and includes AlxGa(1-x)As where 0.2≤x≤0.5.

The second conductive-type semiconductor layer may be doped with a p-type dopant and may include AlxGa(1-x)As where 0.2≤x≤0.5.

The first conductive-type semiconductor layer may include AlGa doped with an n-type dopant and may include a first layer and a second layer, and a composition ratio of Al of the second layer may be greater than that of Al of the first layer.

A thickness of the first layer may be 8 to 9 times a thickness of the second layer.

The second conductive-type semiconductor layer may include AlGa doped with a p-type dopant and may include a first layer and a second layer, and a composition ratio of Al of the second layer may be less than that of Al of the first layer.

A thickness of the second layer may be about four times a thickness of the first layer.

In another embodiment, a light-emitting element includes a light-emitting structure including a first conductive-type semiconductor layer, an active layer, and a second conductive-type semiconductor layer, a first ohmic layer disposed on the first conductive-type semiconductor layer and including an open region formed in a first region, and a second ohmic layer and a transmissive insulating layer that are selectively arranged on the second conductive-type semiconductor layer.

The light-emitting element may further include a first electrode disposed in a second region on the first conductive-type semiconductor layer, wherein the second ohmic layer and the transmissive insulating layer may be selectively arranged in a third region facing the first region and only the transmissive insulating layer may be disposed in a fourth region facing the second region.

The light-emitting element may further include a first electrode disposed in a second region on the first conductive-type semiconductor layer, wherein only the transmissive insulating layer may be disposed in a third region facing the first region and a fourth region facing the second region and the second ohmic layer and the transmissive insulating layer may be selectively arranged between the third region and the fourth region.

A width of the second ohmic layer and the transmissive insulating layer may be largest in a third region facing the first region.

The second ohmic layer may include a plurality of cells and each cell has a size of 5 to 15 micrometers.

In another embodiment, a light-emitting element package includes a body, a first electrode layer and a second electrode layer that are arranged on the body, a light-emitting element including a light-emitting structure disposed on the first electrode layer and including a first conductive-type semiconductor layer, an active layer, and a second conductive-type semiconductor layer, a first ohmic layer disposed on the first conductive-type semiconductor layer and including an open region formed in a first region, a first electrode disposed in a second region on the first ohmic layer, and a second electrode disposed on the second conductive-type semiconductor layer, and a protective layer disposed to surround a partial region of the light-emitting element, wherein the protective layer is open in a region corresponding to the first electrode and the first electrode and the second conductive layer are connected to each other through a wire.

### Advantageous Effects

A light-emitting element according to embodiments may emit light only to a predetermined region and/or in a predetermined direction through an open region on a first ohmic layer and may adjust a proceeding angle of the emitted direction without a cavity disposed on a body of a package.

### DESCRIPTION OF DRAWINGS

FIGS. 1 and 2 are diagram showing a conventional light-emitting element and light-emitting element package.

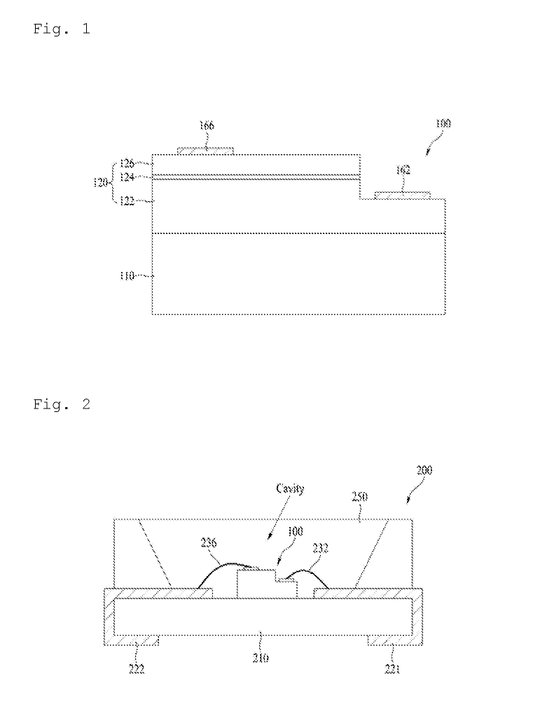

FIG. 3 is a diagram showing a light-emitting element according to a first embodiment.

FIG. 4 is an upper view of FIG. 3.

FIGS. 5A to 5D are cross-sectional views of a light-emitting element according to second to fifth embodiments.

FIGS. 6A to 6D are upper views of FIGS. 5A to 5D, respectively.

FIG. 7 is a diagram showing a driving voltage of a light-emitting element depending on an amount of aluminium (Al) in a first conductive-type semiconductor layer or a second conductive-type semiconductor layer.

FIG. 8 is a diagram showing a light-emitting package in which a light-emitting element is disposed.

FIG. 9 is a diagram showing a mobile device in which a light-emitting element is disposed.

### BEST MODE

Hereinafter, embodiments will be described in detail with reference to the attached drawings.

In the description of the embodiments, it will be understood that, when an element is referred to as being “on” or “under” another element, the term “on” or “under” means that the element is “directly” on or under another element or is “indirectly” formed such that an intervening element may also be present. In addition, it will also be understood that the criteria of “on” or “under” is on the basis of the drawings.

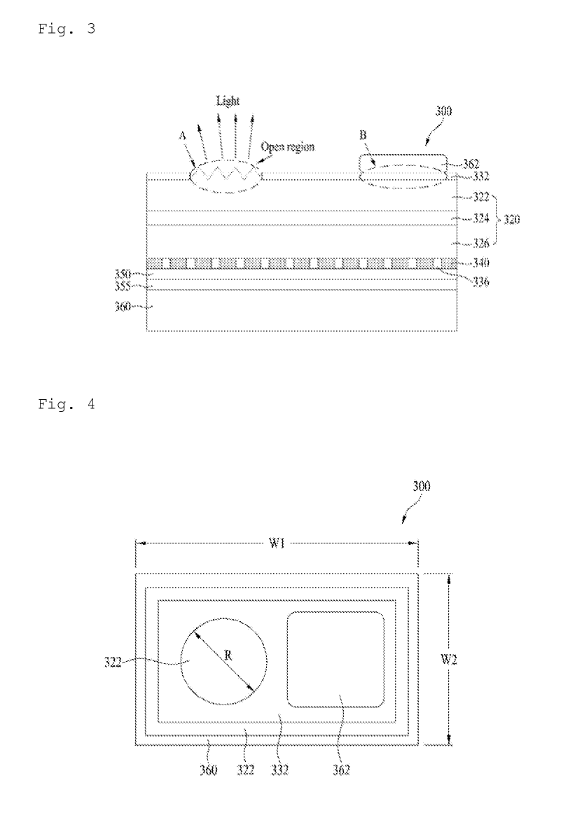

FIG. 3 is a diagram showing a light-emitting element according to a first embodiment.

A light-emitting element 300 according to an embodiment may include a light-emitting structure 220 including a first conductive-type semiconductor layer 322, an active layer 324, and a second conductive-type semiconductor layer 326, a first ohmic layer 332 disposed on the light-emitting structure 320, a first electrode 362 disposed on the first ohmic layer 332, a second ohmic layer 336 and a transmissive insulating layer 340 that are disposed below the light-emitting structure 320, a reflective layer 350 disposed below the second ohmic layer 336 and the transmissive insulating layer 340, and a substrate 360 disposed below the reflective layer 350.

The first conductive-type semiconductor layer 322 may be formed of a compound semiconductor of group III to V, II to VI, or the like and may be doped with a first conductive-type dopant. The first conductive-type semiconductor layer 322 may be formed of any one or more of semiconductor materials represented by an empirical formula of AlₓIn_{y}Ga_{(1-x-y)}N (0≤x≤1, 0≤y≤1, 0≤x+y≤1), i.e., AlGaN, GaN, InAlGaN, AlGaAs, GaP, GaAs, GaAsP, and AlGaInP.

For example, the first conductive-type semiconductor layer 322 may be AlₓGa₍₁₋ₓ₎As doped with an n-type dopant and, in this case, 0.2≤x≤0.5 and, in detail, may be formed by alternately disposing two layers formed of AlₓGa₍₁₋ₓ₎As doped with an n-type dopant. In this case, a first layer included in the first conductive-type semiconductor layer 322 may be formed of Al_{0.2}Ga doped with an n-type dopant and a second layer included in the first conductive-type semiconductor layer 322 may be formed of Al_{0.3}Ga doped with an n-type dopant. In addition, a thickness of the second layer may be about 400 nanometers and a thickness of the first layer may be 8 to 9 times the thickness of the second layer.

When the first conductive-type semiconductor layer 322 is an n-type semiconductor layer, the first conductive-type dopant may include an n-type dopant such as Si, Ge, Sn, Se, and Te. A dopant may be included at a density of 10¹⁷ atoms per cm³ in the first conductive-type semiconductor layer 322.

The active layer 324 may include any one of a single well structure, a multi-well structure, a single quantum well structure, a multi-quantum well (MQW) structure, a quantum point structure, or a quantum line structure and may emit light in a red or infrared ray wavelength region and light in a blue wavelength region.

The active layer 324 may be formed with any one or more of a pair structure of a well layer and a barrier layer using a compound semiconductor material of group III to V element, for example, AlGaN/AlGaN, InGaN/GaN, InGaN/InGaN, AlGaN/GaN, InAlGaN/GaN, GaAs(InGaAs)/AlGaAs, and GaP(InGaP)/AlGaP.

The well layer may be formed of a material with a lower energy band gap than an energy band gap of the barrier layer.

The second conductive-type semiconductor layer 326 may be formed of a semiconductor compound. The second conductive-type semiconductor layer 326 may be formed of a compound semiconductor of group III to V, II to VI, or the like and may be doped with a second conductive-type dopant. The second conductive-type semiconductor layer 326 may be formed of any one or more of semiconductor materials represented by an empirical formula of InₓAl_{y}Ga_{1-x-y}N (0≤x≤1, 0≤y≤1, 0≤x+y≤1), for example, AlGaN, GaN AlInN, AlGaAs, GaP, GaAs, GaAsP, and AlGaInP.

For example, the second conductive-type semiconductor layer 326 may be AlₓGa₍₁₋ₓ₎As doped with a p-type dopant and, in this case, 0.2≤x≤0.5 and, in detail, may be formed by alternately disposing two layers formed of AlₓGa₍₁₋ₓ₎As doped with a p-type dopant. In this case, a first layer included in the second conductive-type semiconductor layer 326 may be formed of Al_{0.33}Ga doped with a p-type dopant and a second layer included in the second conductive-type semiconductor layer 326 may be formed of Al_{0.2}Ga doped with a p-type dopant. In addition, a thickness of the first layer may be about 400 nanometers and a thickness of the second layer may be about four times the thickness of the first layer.

When the second conductive-type semiconductor layer 326 is a p-type semiconductor, the second conductive-type dopant may be a p-type dopant such as Mg, Zn, Ca, Sr, and Ba. A dopant may be included in a density of 10¹⁸ atoms per cm³ in the second conductive-type semiconductor layer 326.

As shown in FIG. 3, the first ohmic layer 332 may be disposed on the first conductive-type semiconductor layer 322, a first region A on the first conductive-type semiconductor layer 322 may be open to form an open region rather than being disposed on the first ohmic layer 332, and the first conductive-type semiconductor layer 322 may be exposed through the open region. In this case, an uneven portion may be formed on a surface of the first conductive-type semiconductor layer 322 exposed through the open region to enhance light extraction efficiency of the light-emitting element 300.

The first ohmic layer 332 may include gold (Au), germanium (Ge), and so on and the second ohmic layer 336 may include silver (Au), zinc (Zn), beryllium (Be), or the like.

The first electrode 362 may be disposed on the first ohmic layer 332 disposed in a second region B on the first conductive-type semiconductor layer 322.

The reflective layer 350 may be disposed below the second conductive-type semiconductor layer 326. The reflective layer 350 may be formed of a material with excellent reflectivity and, for example, may be formed of a conductive material and, in detail, may include a metal layer including tungsten (W), titanium (Ti), molybdenum (Mo), aluminium (Al), silver (Ag), nickel (N), platinum (Pt), or rhodium (Rh), or alloy including Al, Ag, Pt, or Rh. Aluminium, silver, or the like may effectively reflect light directed toward a lower portion of the active layer 324 in FIG. 3 to greatly enhance light extraction efficiency of a light emitting element.

The second ohmic layer 336 and the transmissive insulating layer 340 may be disposed between the second conductive-type semiconductor layer 326 and the reflective layer 350 and may be selectively patterned and arranged as shown in the drawings.

The second ohmic layer 336 may electrically connect the second conductive-type semiconductor layer 326 to the substrate 360 therebelow and the transmissive insulating layer 340 may pass light reflected by the reflective layer 350 in an upward direction of FIG. 3.

The transmissive insulating layer 340 may be formed of an insulating material and the insulating material may include a non-conductive oxide or nitride, for example, a silicon oxide (SiO₂) layer, an oxynitride layer, and an oxide aluminium layer.

The substrate 360 may be disposed below the reflective layer 350 and the substrate 360 may be fixed to the reflective layer 350 through a conductive-type adhesive layer 355 and may function as a second electrode.

The adhesive layer 355 may be formed of a material selected from the group consisting of, for example, gold (Au), tin (Sn), indium (In), aluminium (Al), silicon (Si), silver (Ag), nickel (Ni), and copper (Cu) or an alloy thereof.

The substrate 360 may be formed of a conductive material, for example, metal or a semiconductor material. The substrate 360 may be formed of metal with excellent electrical conductivity or thermal conductivity and is capable of sufficiently dissipating heat generated during an operation of a light-emitting element and, thus, may be formed of a material with high thermal conductivity. For example, the substrate 360 may be formed of a material selected from the group consisting of silicon (Si), molybdenum (Mo), silicon (Si), tungsten (W), copper (Cu), and aluminium (Al) or an alloy thereof and may selectively include gold (Au), Cu alloy, nickel (N), copper-tungsten (Cu—W), a carrier wave (e.g., GaN, Si, Ge, GaAs, ZnO, SiGe, SiC, SiGe, or Ga₂O₃), or the like.

The substrate 360 may have mechanical strength for appropriately separating the light-emitting structure 320 as separate chips through a scribing process and a breaking process without bending of an entire portion of the light-emitting structure 320.

The light-emitting element 100 according to the aforementioned embodiment may allow light emitted from the active layer 324 to proceed only through an open region of the first ohmic layer 332 and to be emitted only to a predetermined region.

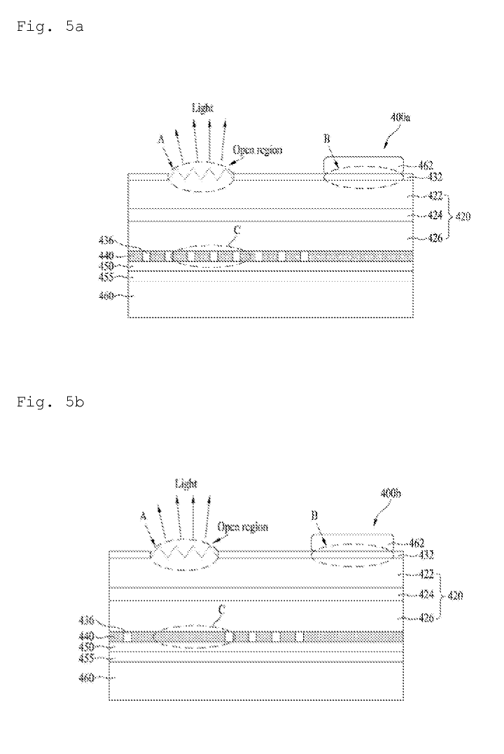

FIG. 4 is an upper view of the light-emitting element of FIG. 3.

In FIG. 4, the first conductive-type semiconductor layer 322 may be exposed through an open region on an upper surface of the light-emitting element 300 and a size R of the open region may be 80 to 160 micrometers. The open region may be a different shape such as a polygonal shape other than a circular shape. The size R of the open region may be changed according to a size of the light-emitting element 300.

A size of the substrate 360 is larger than a size of a light-emitting structure and, thus, the substrate 360 may protrude out of an edge of the first conductive-type semiconductor layer 322 in FIG. 4. A length W1 of the substrate 360 in a horizontal direction may be 320 micrometers and may have a tolerance of ±25 micrometers and a length W2 of the substrate 360 in a vertical direction may be 220 micrometers and may have tolerance of ±25 micrometers. In addition, a height of the light-emitting element may be 175 micrometers and may have predetermined tolerance.

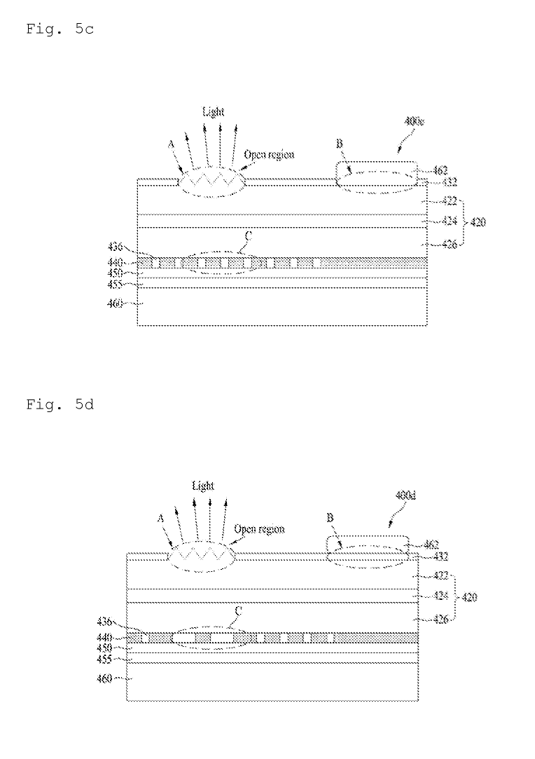

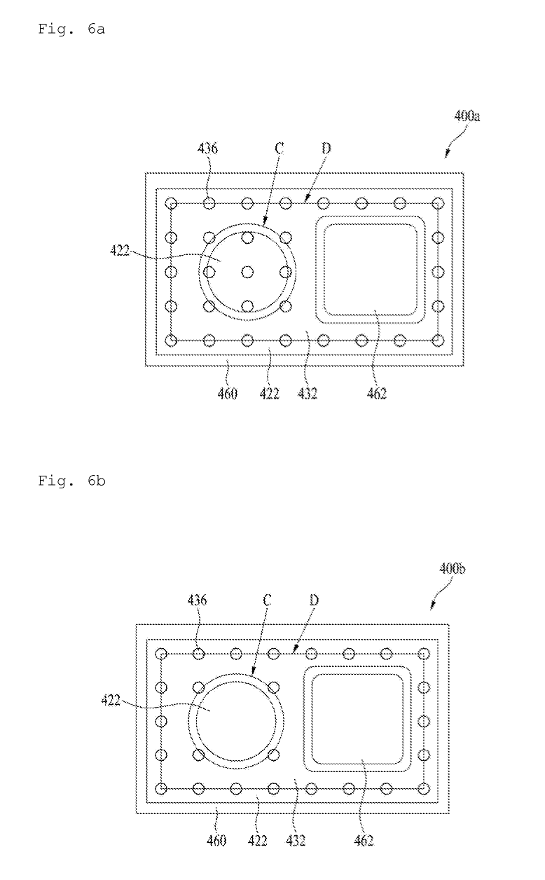

FIGS. 5A to 5D are cross-sectional views of a light-emitting element according to second to fifth embodiments and FIGS. 6A to 6D are upper views of FIGS. 5A to 5D, respectively.

Light-emitting elements 400a to 400d shown in FIGS. 5A to 5D are similar to the embodiment of FIG. 3 but the arrangements of a second ohmic layer 436 and a transmissive insulating layer 440 are different.

In the light-emitting element 400a of FIG. 5A, the second ohmic layer 436 and the transmissive insulating layer 440 may be disposed between a second conductive-type semiconductor layer 426 and a reflective layer 450, and the second ohmic layer 436 and the transmissive insulating layer 440 may be patterned and selectively arranged in a third region C which correspond to an open region of a first region A in a perpendicular direction.

In FIGS. 5A and 6A, the second ohmic layer 436 and the transmissive insulating layer 440 may be selectively arranged in the third region C and only the transmissive insulating layer 440 may be disposed in a third region facing the second region. In addition, the second ohmic layer 436 may be patterned and arranged in a fifth region D at an edge and only the transmissive insulating layer 440 may be arranged in a region between the third region C and the fifth region D.

In FIGS. 5B and 6B, the second ohmic layer 436 and the transmissive insulating layer 440 may be arranged between the second conductive-type semiconductor layer 426 and the reflective layer 450, and only the transmissive insulating layer 440 may be disposed in the third region C corresponding to the open region of the first region A in a perpendicular direction and a fourth region corresponding to the second region in a perpendicular direction.

In FIGS. 5B and 6B, the second ohmic layer 436 and the transmissive insulating layer 440 may be patterned and arranged between the third region C and the fourth region. The second ohmic layer 436 and the transmissive insulating layer 440 may also be patterned and arranged in a circumferential region of the third region C at an edge and the fifth region D at an edge.

The fourth embodiment of the light-emitting elements shown in FIGS. 5C and 6C is similar to the second embodiment of the light-emitting elements shown in FIGS. 5A and 6A except that a first electrode 462 directly contacts a first conductive-type semiconductor layer 422. That is, a first ohmic layer 432 may not be disposed in the second region B on the first conductive-type semiconductor layer 422 and the first electrode 462 may be disposed in the second region B.

The fifth embodiment of the light-emitting element shown in FIGS. 5D and 6D is similar to the second embodiment of the light-emitting element shown in FIGS. 5A and 6A except that widths and sizes of the second ohmic layer 436 and the transmissive insulating layer 440 are larger in the third region C. That is, a size of the second ohmic layer 436 disposed in the third region C corresponding to an open region may be larger than a size of the second ohmic layer 436 disposed in the fifth region D at an edge of a light-emitting structure. For example, the second ohmic layer 436 formed in the third region C may be shaped like a line or a circular arc, but not a dot.

In a light-emitting element according to embodiments, the second ohmic layer 436 may include a plurality of cells and each cell may have a size of 5 to 15 micrometers. Here, the ‘size’ refers to a diameter or a side of each cell.

When a size of each of the aforementioned cells is less than 5 micrometers, amplitude of supplied current may be reduced in a direction toward the second conductive-type semiconductor layer 426 from a second electrode to increase a driving voltage of a light-emitting element. When a size of each of the aforementioned cells is greater than 15 micrometers, an amount of light shielded in cells included in the second ohmic layer 436 from light reflected by the reflective layer 450 may be increased to cause light loss in the light-emitting element.

The sum of cross sections of the second ohmic layers 436 in a horizontal direction may be 3% to 4% of a cross section of an active layer 424 in a horizontal direction. When the aforementioned sum of the cross sections of the second ohmic layers 436 is less than 3%, current may not be smoothly supplied to the second conductive-type semiconductor layer 436 and, when the sum of the cross sections of the second ohmic layers 436 is greater than 4%, an amount of light re-reflected by the second ohmic layer 436 from light reflected by the reflective layer 450 may be increased.

To uniformly supply current to an entire region of the second conductive-type semiconductor layer 426, cells included in the second ohmic layer 436 may have a dot shape, which is more advantageous than a line shape or a circular arc shape.

Table 1 below shows a driving voltage and output in the aforementioned second to fifth embodiments of the aforementioned light-emitting element and shows a driving voltage and output when current of 50 mA is supplied to the light-emitting element.

TABLE 1

| | Embodiment | Embodiment | Embodiment | Embodiment |
|---|---|---|---|---|
| | 2 | 2 | 3 | 4 |
| Driving | 1.55 | 1.59 | 1.58 | 1.60 |
| Voltage (V) | | | | |
| Output (mW) | 3.57 | 2.99 | 3.52 | 3.56 |

As seen from Table 1 above, a driving voltage is lowest and output is highest in the second embodiment of the light-emitting element.

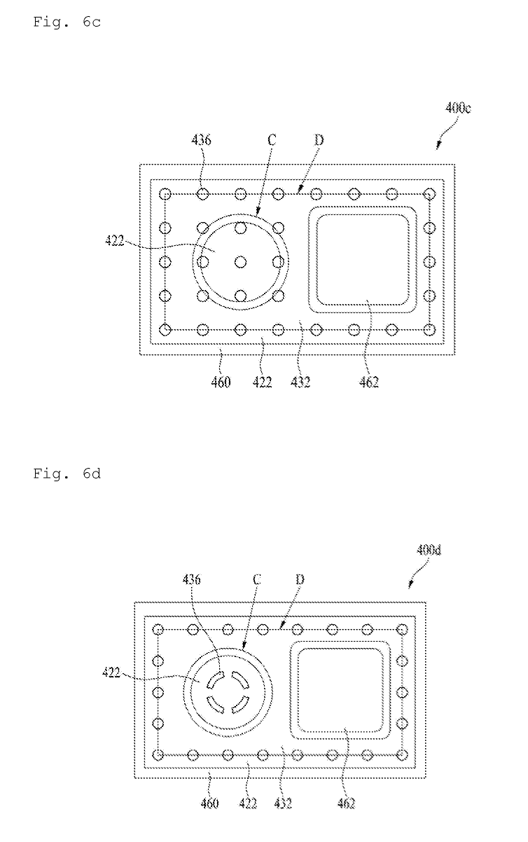

FIG. 7 is a diagram showing a driving voltage of a light-emitting element depending on an amount of aluminium (Al) in the first conductive-type semiconductor layer 422 or the second conductive-type semiconductor layer 426.

As illustrated in the drawings, it may be seen that, when a concentration of aluminium in the first conductive-type semiconductor layer 422 or the second conductive-type semiconductor layer 426 represented by AlₓGa₍₁₋ₓ₎As is less than 0.2, optical efficiency of a light-emitting element may be degraded. In addition, when a concentration of aluminium is greater than 0.5, resistance in a semiconductor layer may be increased and a driving voltage of a light-emitting element may be increased.

The aforementioned light-emitting element may emit light in various wavelength regions depending on composition of an active layer and, for example, may emit light in an infrared or red wavelength region.

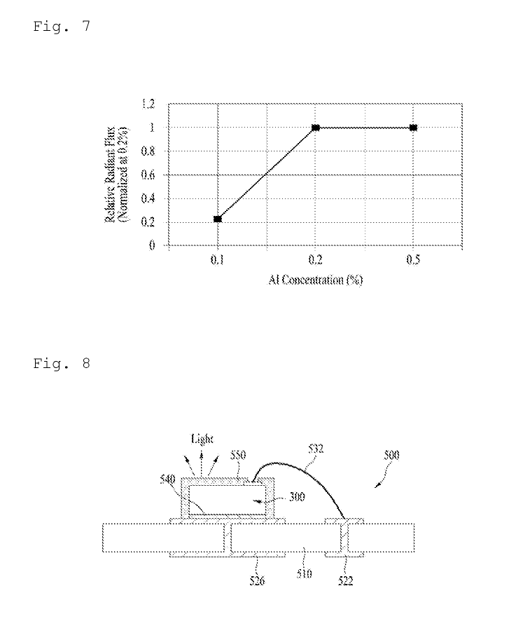

FIG. 8 is a diagram showing a light-emitting package in which a light-emitting element is disposed.

A light-emitting package 500 may be configured in such a way that a first electrode layer 522 and a second electrode layer 526 are disposed in a body 510, and the aforementioned light-emitting element 300 is electrically connected to the first electrode layer 522 through a conductive adhesive layer 540 and is electrically connected to the second electrode layer 526 through a wire 532.

In detail, a protective layer 550 may be arranged to surround a partial region of the light-emitting element 300 and may be open in a region corresponding to the first electrode, and the first electrode and the second conductive layer 522 may be connected to each other through the wire 532.

The protective layer 550 may be arranged at a circumference of the light-emitting element 300 and may be a passivation layer or a molding portion. The protective layer 550 may include a fluorescent substance and, in this case, the fluorescent substance may be excited by light in a first wavelength region, emitted from the light-emitting element 300, to emit light in a second wavelength region.

The aforementioned light-emitting package 500 may emit light only to a predetermined region and/or in a predetermined region through an open region in the light-emitting element 300 and, thus, may adjust a proceeding angle of the emitted light without a cavity disposed in the body 510, unlike in the prior art.

The aforementioned light-emitting element and light-emitting element package may be used as a light source of an illumination system and, for example, may be used as a backlight unit of an image display device and a light source of a lamp device or a vehicular illumination device.

When used as a vehicular illumination device, the light-emitting element and the light-emitting element package may be used as headlights or taillights or as a light source of an indicator.

Since the aforementioned light-emitting element and light-emitting package may not include a cavity in a body, the light-emitting element and the light-emitting package may adjust a proceeding angle of light while reducing a volume of the element and package and, thus, may be used as a light source of a miniaturized device, in particular, a mobile terminal.

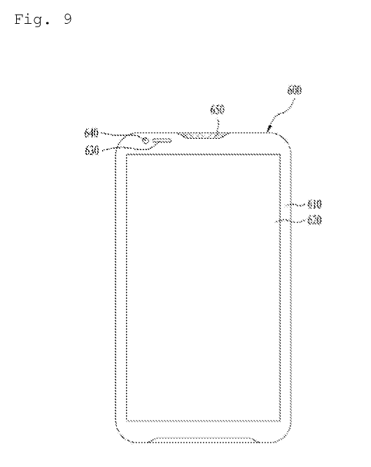

FIG. 9 is a diagram showing a mobile terminal in which a light-emitting element package is disposed.

A display 620 may be disposed in a housing 610 of a mobile terminal 600 and a cover portion 650 for protecting a sound output unit (not shown) may be disposed in an upper central portion of the housing 610.

A camera module 630 and a light source 640 may be arranged adjacent to the cover portion 650, the light source 640 may be the aforementioned light-emitting element or light-emitting element package, and the light source 640 may be arranged on a front surface of the housing 610, as shown in FIG. 8 or may be arranged on a rear surface of the housing 610.

Although embodiments have been described with reference to a number of illustrative embodiments thereof, it should be understood that numerous other modifications and applications may be devised by those skilled in the art that will fall within the intrinsic aspects of the embodiments. More particularly, various variations and modifications are possible in concrete constituent elements of the embodiments. In addition, it is to be understood that differences relevant to the variations and modifications fall within the spirit and scope of the present disclosure defined in the appended claims.

### INDUSTRIAL APPLICABILITY

A light-emitting element according to embodiments may be used as a light source and, in particular, when the light-emitting element is used as a light source of a mobile device, a proceeding angle of light may be adjusted while reducing a volume of the light source.

1. A light-emitting element comprising:
a light-emitting structure including a first conductive-type semiconductor layer, an active layer, and a second conductive-type semiconductor layer;
a first ohmic layer disposed on the first conductive-type semiconductor layer and including an open region formed in a first region;
a first electrode disposed in a second region on the first ohmic layer; and
a second electrode disposed on the second conductive-type semiconductor layer,
wherein an uneven portion is formed on an upper surface of the first conductive-type semiconductor layer at the open region, and an upper surface of the first conductive-type semiconductor layer at the other region is flat.

2. The light-emitting element of claim 1, further comprising a reflective layer disposed between the second conductive-type semiconductor layer and the second electrode.

3. The light-emitting element of claim 2, further comprising a second ohmic layer disposed between the second conductive-type semiconductor layer and the reflective layer.

4. The light-emitting element of claim 3, further comprising a transmissive insulating layer disposed between the second conductive-type semiconductor layer and the reflective layer, wherein the second ohmic layer is patterned and arranged.

5. The light-emitting element of claim 4, wherein the second ohmic layer is arranged in a third region corresponding to the open region and a fourth region at an edge of the light-emitting structure.

6. The light-emitting element of claim 5, wherein the transmissive insulating layer is disposed in an entire region between the third region and the fourth region between the second conductive-type semiconductor layer and the reflective layer.

7. The light-emitting element of claim 3, wherein the sum of cross sections of the second ohmic layers in a horizontal direction is 3% to 4% of a cross section of the active layer in a horizontal direction.

8. The light-emitting element of claim 3, wherein the second ohmic layer includes a plurality of cells and each cell has a size of 5 to 15 micrometers in a horizontal direction.

9. The light-emitting element of claim 1, wherein the first conductive-type semiconductor layer is doped with an n-type dopant and includes AlₓGa₍₁₋ₓ₎As where 0.2≤x≤0.5, and the second conductive-type semiconductor layer is doped with a p-type dopant and includes AlₓGa₍₁₋ₓ₎As where 0.2≤x≤0.5.

10. (canceled)

11. The light-emitting element of claim 1, wherein the first conductive-type semiconductor layer includes AlGa doped with an n-type dopant and includes a first layer and a second layer, and a composition ratio of Al of the second layer is greater than that of Al of the first layer.

12. The light-emitting element of claim 11, wherein a thickness of the first layer is 8 to 9 times a thickness of the second layer.

13. The light-emitting element of claim 1, wherein the second conductive-type semiconductor layer includes AlGa doped with a p-type dopant and includes a first layer and a second layer, and a composition ratio of Al of the second layer is less than that of Al of the first layer.

14. The light-emitting element of claim 13, wherein a thickness of the second layer is about four times a thickness of the first layer.

15. A light-emitting element comprising:
a light-emitting structure including a first conductive-type semiconductor layer, an active layer, and a second conductive-type semiconductor layer;
a first ohmic layer disposed on the first conductive-type semiconductor layer and including an open region formed in a first region; and
a second ohmic layer and a transmissive insulating layer that are selectively arranged on the second conductive-type semiconductor layer,
wherein an uneven portion is formed on an upper surface of the first conductive-type semiconductor layer at the open region, and an upper surface of the first conductive-type semiconductor layer at the other region is flat.

16. The light-emitting element of claim 15, further comprising a first electrode disposed in a second region on the first conductive-type semiconductor layer,
wherein the second ohmic layer and the transmissive insulating layer are selectively arranged in a third region facing the first region and only the transmissive insulating layer is disposed in a fourth region facing the second region.

17. The light-emitting element of claim 15, further comprising a first electrode disposed in a second region on the first conductive-type semiconductor layer,
wherein only the transmissive insulating layer is disposed in a third region facing the first region and a fourth region facing the second region and the second ohmic layer and the transmissive insulating layer are selectively arranged between the third region and the fourth region.

18. The light-emitting element of claim 15, wherein a width of the second ohmic layer and the transmissive insulating layer is largest in a third region facing the first region.

19. The light-emitting element of claim 15, wherein the second ohmic layer includes a plurality of cells and each cell has a size of 5 to 15 micrometers.

20. A light-emitting element package comprising:
a body;
a first electrode layer and a second electrode layer that are arranged on the body;
a light-emitting element including a light-emitting structure disposed on the first electrode layer and including a first conductive-type semiconductor layer, an active layer, and a second conductive-type semiconductor layer, a first ohmic layer disposed on the first conductive-type semiconductor layer and including an open region formed in a first region, a first electrode disposed in a second region on the first ohmic layer, and a second electrode disposed on the second conductive-type semiconductor layer; and
a protective layer disposed to surround a partial region of the light-emitting element,
wherein the protective layer is open in a region corresponding to the first electrode and the first electrode and the second electrode are connected to each other through a wire, and
wherein an uneven portion is formed on an upper surface of the first conductive-type semiconductor layer at the open region, and an upper surface of the first conductive-type semiconductor layer at the other region is flat.

21. The light-emitting element of claim 1, wherein a height of the uneven portion formed on an upper surface of the first conductive-type semiconductor layer at the open region is higher than a height of an upper surface of the first conductive-type semiconductor layer at the other region.
